(19) United States
(12) Patent Application Publication
(10) Pub. No.: US 2023/0163233 A1
(43) Pub. Date: May 25, 2023

(54) NANOWIRE LED, DISPLAY MODULE INCLUDING THE NANOWIRE LED, AND METHOD FOR MANUFACTURING THE DISPLAY MODULE

(71) Applicant: SAMSUNG ELECTRONICS CO., LTD., Suwon-si (KR)

(72) Inventors: Myunghee KIM, Suwon-si (KR); Sungwook Kim, Suwon-si (KR); Yong Namkung, Suwon-si (KR)

(73) Assignee: SAMSUNG ELECTRONICS CO., LTD., Suwon-si (KR)

(21) Appl. No.: 18/094,112

(22) Filed: Jan. 6, 2023

Related U.S. Application Data
(63) Continuation of application No. PCT/KR21/07210, filed on Jun. 9, 2021.

(30) Foreign Application Priority Data
Jul. 7, 2020 (KR) 10-2020-0083658
Nov. 30, 2020 (KR) 10-2020-0164884

(51) Int. Cl. H01L 33/02; H01L 25/16; H01L 33/00; H01L 23/00

(52) U.S. Cl. CPC H01L 33/02; H01L 25/167; H01L 33/007; H01L 33/0093; H01L 24/95; H01L 33/32

(57) ABSTRACT

A nanowire LED, a display module including the nanowire LED, and a method for manufacturing the display module are provided. The method for manufacturing a display module includes forming a template layer including a magnetic layer on a silicon substrate, growing a plurality of nanowire LEDs on the template layer, separating the plurality of nanowire LEDs from the template layer by ultrasonic waves, forming a plurality of unit cells in a state in which the plurality of nanowire LEDs are aligned to have a specific directivity, forming a plurality of unit pixels by transferring the plurality of unit cells onto a unit substrate, arranging the plurality of unit pixels on a thin film transistor (TFT) substrate through a fluidic self-assembly, and bonding the plurality of unit pixels to be connected to an electrode of the TFT substrate.

### CROSS-REFERENCE TO RELATED APPLICATION(S)

This application is a bypass continuation of International Application No. PCT/KR2021/007210, filed on Jun. 9, 2021, which is based on and claims priority to Korean Patent Application No. 10-2020-0164884, filed on Nov. 30, 2020, and Korean Patent Application No. 10-2020-0083658, filed on Jul. 7, 2020, in the Korean Intellectual Property Office, the disclosures of which are incorporated by reference herein in their entireties.

### BACKGROUND

### 1. Field

The disclosure relates to a nanowire light emitting diode (LED) and a method for manufacturing the same, and in particular, to a display module to which nanowire LEDs are transferred by a fluidic self-assembly (FSA) method, and a method for manufacturing the same.

### 2. Description of Related Art

A display module expresses various colors as it is operated in a pixel unit or a sub-pixel unit. In this case, one sub-pixel includes a plurality of nanowire LEDs.

Operations of each pixel or sub-pixel are controlled by a plurality of thin film transistors (TFTs). A TFT substrate may include a flexible substrate, a glass substrate, or a plastic substrate on which a TFT circuit is formed. On a TFT substrate, a plurality of TFTs connected to a TFT circuit are mounted.

Recently, a display device having a big screen (a large format display) is being manufactured by connecting a plurality of display modules.

### SUMMARY

Provided is a three-dimensional nanowire light emitting diode (LED) which may secure an n-type contact area without a separate etching process after epitaxial growth, and having a magnetic property so as to be aligned by a magnetic field.

Further, provided are a display module to which nanowire LEDs are transferred through a hybrid fluidic self-assembly (FSA) process, and a method for manufacturing the same.

Additional aspects will be set forth in part in the description which follows and, in part, will be apparent from the description, or may be learned by practice of the presented embodiments.

According to an aspect of the disclosure, a nanowire light emitting diode (LED) may include an n-type GaN-based semiconductor layer having a pillar shape, an active layer provided on a first side of the n-type GaN-based semiconductor layer, a p-type GaN-based semiconductor layer provided on the active layer, and a magnetic layer provided on a second side of the n-type GaN-based semiconductor layer.

The magnetic layer may be provided on an end part of the second side of the n-type GaN-based semiconductor layer.

The magnetic layer may include a diamagnetic material.

The diamagnetic material may include Ge.

The magnetic layer may include a material having a magnetic property.

The material having the magnetic property may include Cr, Mn, Fe, Co, Ni, or Cu.

The magnetic layer may include at least one first thin film layer comprising a diamagnetic material or a material having a magnetic property, and at least one second thin film layer comprising an n-type semiconductor, where the at least one first thin film layer and the at least one second thin film layer are alternatingly stacked.

According to an aspect of the disclosure, a display module may include a thin film transistor (TFT) substrate comprising a plurality of anode electrodes and a plurality of cathode electrodes provided on a first surface of the TFT substrate, and a plurality of nanowire LEDs including first end parts respectively connected to each anode electrode and second end parts respectively connected to each cathode electrode, where each of the plurality of nanowire LEDs may have a magnetic property and polarity.

The plurality of nanowire LEDs may include an n-type GaN-based semiconductor layer having a pillar shape, an active layer provided on a first side of the n-type GaN-based semiconductor layer, a p-type GaN-based semiconductor layer provided on the active layer, and a magnetic layer provided on a second side of the n-type GaN-based semiconductor layer.

The plurality of nanowire LEDs may be provided to the TFT substrate in a form of a unit pixel comprising red, green, and blue sub-pixels, and the unit pixel may include a unit substrate on which the red, green, and blue sub-pixels are provided.

According to an aspect of the disclosure, a method for manufacturing a display module may include forming a template layer including a magnetic layer on a silicon substrate, growing a plurality of nanowire LEDs on the template layer, separating the plurality of nanowire LEDs from the template layer by ultrasonic waves, forming a plurality of unit cells in a state in which the plurality of nanowire LEDs are aligned to have a specific directivity, forming a plurality of unit pixels by transferring the plurality of unit cells onto a unit substrate, arranging the plurality of unit pixels on a TFT substrate through an FSA, and bonding the plurality of unit pixels to be connected to an electrode of the TFT substrate.

The forming the template layer may include forming a first n-type GaN-based semiconductor layer on the silicon substrate, forming the magnetic layer by alternatingly stacking at least one first thin film layer including an n-type semiconductor and at least one second thin film layer including a diamagnetic material or a material having a magnetic property on the first n-type GaN-based semiconductor layer, and forming a second n-type GaN-based semiconductor layer on the magnetic layer.

The diamagnetic material may include Ge, and the material having the magnetic property may include Cr, Mn, Fe, Co, Ni, or Cu.

The method may further include, prior to growing the plurality of nanowire LEDs, patterning a filling part on the template layer, and infiltrating a filling material having flexibility into the filling part.

The method may further include setting a length of an exposed part of the plurality of nanowire LEDs based on a depth of the filling part.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram illustrating a display module according to an embodiment of the disclosure;

FIG. 2 is a flowchart illustrating a manufacturing process of a display module according to an embodiment of the disclosure;

FIG. 3 is a diagram illustrating an example of forming a GaN-based template layer on a substrate according to an embodiment of the disclosure;

FIG. 4 is a diagram illustrating an example of forming a plurality of grooves by etching a part of a GaN-based template layer according to an embodiment of the disclosure;

FIG. 5 is a diagram illustrating an example of inserting a filling material into a plurality of grooves formed on a GaN-based template layer according to an embodiment of the disclosure;

FIG. 6 is a diagram illustrating an example of growing a plurality of nanowire light emitting diodes (LEDs) in a three-dimensional shape on a GaN-based template layer according to an embodiment of the disclosure;

FIG. 7 is a diagram illustrating an example of separating a plurality of nanowire LEDs from a substrate by using ultrasonic waves according to an embodiment of the disclosure;

FIG. 8 is a cross-sectional view illustrating nanowire LEDs separated from a substrate according to an embodiment of the disclosure;

FIG. 9 is a diagram illustrating an example of introducing a plurality of nanowire LEDs into a tank including a polymer compound according to an embodiment of the disclosure;

FIG. 10 is a diagram illustrating an example where a plurality of nanowire LEDs are respectively coupled to a plurality of ring-shaped compounds included in a polymer compound according to an embodiment of the disclosure;

FIG. 11 is a diagram illustrating an example of infiltrating nanowire LEDs coupled with a polymer compound into a plurality of molding grooves formed on a mold, and forming a magnetic field around the mold according to an embodiment of the disclosure;

FIG. 12 is a diagram illustrating an example wherein a plurality of nanowire LEDs arranged in a unit cell are aligned in a specific direction by a magnetic field according to an embodiment of the disclosure;

FIG. 13 is a diagram illustrating an example of transferring red/green/blue nanowire LEDs constituting one pixel to a unit substrate according to an embodiment of the disclosure;

FIG. 14 is a diagram illustrating a state where nanowire LEDs in a unit cell form are transferred to the unit substrate illustrated in FIG. 13 according to an embodiment of the disclosure;

FIG. 15 is a diagram illustrating a plurality of nanowire LEDs connected to an anode electrode and a cathode electrode on a unit substrate according to an embodiment of the disclosure;

FIG. 16 is a diagram illustrating an example of arranging a plurality of unit pixels on a thin film transistor (TFT) substrate through fluidic self-assembly (FSA) according to an embodiment of the disclosure;

FIG. 17 is a diagram illustrating a state where a plurality of unit pixels arranged on a TFT substrate are bonded to electrodes of the TFT substrate according to an embodiment of the disclosure; and

FIG. 18 is a diagram illustrating a display module according to an embodiment of the disclosure.

### DETAILED DESCRIPTION

Hereinafter, various embodiments will be described in more detail with reference to the accompanying drawings. The embodiments described in this specification may be modified in various ways. Also, specific embodiments may be illustrated in the drawings, and described in detail in the detailed description. However, specific embodiments disclosed in the accompanying drawings are just for making the various embodiments easily understood. Accordingly, the technical idea of the disclosure is not restricted by the specific embodiments disclosed in the accompanying drawings, and the embodiments should be understood as including all equivalents or alternatives included in the idea and the technical scope of the disclosure.

Also, terms including ordinal numbers such as “the first” and “the second” may be used to describe various components, but these components are not limited by the aforementioned terms. The aforementioned terms are used only for the purpose of distinguishing one component from another component.

In addition, in this specification, terms such as “include” and “have” should be construed as designating that there are such characteristics, numbers, steps, operations, elements, components or a combination thereof described in the specification, but not as excluding in advance the existence or possibility of adding one or more of other characteristics, numbers, steps, operations, elements, components or a combination thereof. Further, the description in the disclosure that an element is “coupled with/to” or “connected to” another element should be interpreted to mean that the one element may be directly coupled with/to or connected to the another element, but still another element may exist between the elements. In contrast, the description that one element is “directly coupled” or “directly connected” to another element may be interpreted to mean that still another element does not exist between the one element and the another element.

Also, the expression ‘identical’ not only means that some features perfectly coincide, but also means that the features include a difference in consideration of a machining error range.

Other than the above, in describing the disclosure, in case it is determined that detailed explanation of related known functions or components may unnecessarily confuse the gist of the disclosure, the detailed explanation will be abridged or omitted.

A display module may be a display panel on which nanowire light emitting diodes (LEDs) (nanowire LEDs or NW LEDs) are mounted. The display module is a kind of flat display panels, and it includes a plurality of inorganic LEDs which are respectively 100 micrometers or smaller. Compared to a liquid crystal display (LCD) panel which needs a backlight, a nanowire LED display module provides better contrast, response time, and energy efficiency. Both of an organic LED (OLED) and a nanowire LED which is an inorganic light emitting element have good energy efficiency, but a nanowire LED has better brightness and light emitting efficiency, and a longer lifespan than an OLED. A nanowire LED may be a semiconductor chip that may emit a light by itself in case power is supplied. A nanowire LED has a fast reaction speed, low power consumption, and high luminance. Specifically, a nanowire LED has higher efficiency in converting electrons to photons compared to a conventional liquid crystal display (LCD) or an OLED. That is, a nanowire LED has higher “brightness per watt” compared to a conventional LCD or an OLED display. Accordingly, a nanowire LED may exert the same brightness even with approximately half the energy compared to a conventional LED (the width, length, and height respectively exceed 100 μm) or an OLED. In addition, a nanowire LED may implement a high resolution, and superior colors, contrast, and brightness, and may thus express colors in a wide range precisely, and may implement a clear screen even in the outdoors where sunlight is bright. Also, a nanowire LED is strong against a burn-in phenomenon and emits a small amount of heat, and thus a long lifespan is guaranteed without deformation.

A nanowire LED is a semiconductor self luminous element that was grown in a three-dimensional shape on a silicon substrate, and it may constitute a so-called core/shell structure where different materials in a hetero-j unction diode structure are stacked in a radial form with respect to one another. The size of one nanowire LED may be from scores of nm to scores of μm. In the disclosure, one ‘nanowire LED’ may be used as the same meaning as one sub-pixel.

A nanowire LED may include a plurality of nanowires. A nanowire LED may include a part of a template layer for growth where a III-Nitride GaN-based (e.g., the general formula is AlxGayIn1-x-yN) semiconductor layer in a hexagonal crystal structure having polarity is used as a light emitting layer, and a diamagnetic material (e.g., Ge), or a material having a magnetic property (e.g., Cr, Mn, Fe, Co, Ni, and Cu) is used as a buffer layer.

A nanowire LED may be epitaxially grown three-dimensionally by a bottom-up method, and constitute a pillar shape in a nano size. As a nanowire LED may include a magnetic material, it may be aligned in a specific direction by a magnetic field in a later process.

A nanowire LED grown on a GaN-based template layer may be separated from the GaN-based template layer by using ultrasonic waves. Accordingly, damage exerted on the nanowire LED during a separation process may be minimized.

A nanowire LED emitting a red color is epitaxially grown on a GaN-based template layer identical to a nanowire LED emitting a green color or a blue color, and accordingly, the epitaxial growth platform may be unified, and the manufacturing efficiency may be improved.

A plurality of nanowires go through a molding processing in a state of being coupled by a super high polymer compound having a cross-linking property in a chain-polymer network form, and are encapsulated. The super high polymer compound may be, for example, polyrotaxane. Unit cells molded in a form as above may be manufactured.

If a magnetic field is flown to a unit cell before bonding a p-type semiconductor layer and an n-type semiconductor layer to an anode electrode and a cathode electrode of a thin film transistor (TFT) substrate, a plurality of nanowires included in the unit cell may be arranged to have directivity such that all of the respective p-type semiconductor layers are toward the same direction, and all of the respective n-type semiconductor layers are toward the same direction.

If a magnetic field is flown after transferring the unit cell including the plurality of nanowires arranged in a state of having directivity to a predetermined location (e.g., the corresponding sub-pixel area) of the TFT substrate, the plurality of nanowires may be arranged such that the p-type semiconductor layer is toward the anode electrode, and the n-type semiconductor layer is toward the cathode electrode. In the unit cell arranged in each sub-pixel area of the TFT substrate, the polymer compound may be removed through a removing process. In a state where the polymer compound has been removed, in the plurality of nanowires, the p-type semiconductor layer may be electronically and physically connected to the anode electrode, and the n-type semiconductor layer may be electronically and physically connected to the cathode electrode through a bonding process.

In the disclosure, one pixel may include at least three sub-pixels. The three sub-pixels may include nanowire LEDs that may express R/G/B full colors.

The plurality of sub-pixels may be mounted on a subminiature substrate (e.g., a substrate having a size of a degree corresponding to a pixel area). In this case, the subminiature substrate and the plurality of sub-pixels mounted thereon may together be referred to as one pixel unit as a single unit. A plurality of pixel units may be transferred to another TFT substrate by a fluidic self-assembly (FSA) method.

In the disclosure, on the front surface of a glass substrate, a TFT layer where a thin film transistor (TFT) circuit is formed may be arranged, and on the rear surface, a circuit that supplies power to the TFT circuit, and is electronically connected to a separate control substrate may be arranged. The TFT circuit may operate a plurality of pixels arranged on the TFT layer.

The front surface of the glass substrate may be divided into an active area and a dummy area. The active area may fall under an area occupied by the TFT layer on the front surface of the glass substrate, and the dummy area may fall under the area excluding the area occupied by the TFT layer on the front surface of the glass substrate.

The edge area of the glass substrate may be the outermost part of the glass substrate. Also, the edge area of the glass substrate may be the remaining area of the glass substrate excluding the area where the circuit is formed. Further, the edge area of the glass substrate may include the side surface of the glass substrate, a part of the front surface of the glass substrate adjacent to the side surface, and a part of the rear surface of the glass substrate. The glass substrate may be formed of a quadrangle type. Specifically, the glass substrate may be formed of a rectangle or a square. The edge area of the glass substrate may include at least one side among the four sides of the glass substrate.

In the edge area of the glass substrate, a plurality of side surface wirings may be formed at a specific interval from one another. One end part of the plurality of side surface wirings may be electronically connected to a plurality of first connection pads formed in an edge area included in the front surface of the glass substrate, and the other end part may be electronically connected to a plurality of second connection pads formed in an edge area included in the rear surface of the glass substrate. The plurality of first connection pads may be connected to the TFT circuit arranged on the front surface of the glass substrate through the wirings, and the plurality of second connection pads may be connected to a driving circuit arranged on the rear surface of the glass substrate through the wirings.

As a plurality of side wirings are formed in the display module, the dummy area is minimized and the active area is maximized on the front surface of the TFT substrate, and accordingly, the display module may become bezel-less, and the mounting density of micro LEDs for the display module may be increased. In case a plurality of such display modules having a bezel-less implementation are connected, a large format display (LFD) device that may maximize the active area may be provided. In this case, as the dummy area of each display module is minimized, pitches among each pixel of adjacent display modules may be formed to be maintained identical to the pitches among each pixel in a single display module. Accordingly, appearance of seams in the connecting portions between each display module may be prevented.

An example where a plurality of side surface wirings are formed at a specific interval from one another in the respective edge areas corresponding to two sides facing each other among the edge areas corresponding to the four sides of the glass substrate is suggested. However, the disclosure is not limited thereto, and a plurality of side surface wirings may be formed at a specific interval from one another in the edge areas corresponding to two sides adjacent to each other. Also, a plurality of side surface wirings may be formed at a specific interval from one another only in the edge area corresponding to one side among the edge areas corresponding to the four sides, but a plurality of side surface wirings may also be formed at a specific interval from one another in the edge areas corresponding to three sides, depending on needs.

The display module includes a glass substrate on which a plurality of LEDs are mounted, and side surface wirings are formed. Such a display module may be installed and applied in a single unit on wearable devices, portable devices, handheld devices, and various kinds of electronic products or electronic components which need displays. Also, the display module may be applied as a matrix type to display devices such as monitors for personal computers (PCs), high resolution TVs and signage (or, digital signage), and electronic displays through a plurality of assembly arrangements.

Hereinafter, the display module according to an embodiment of the disclosure will be described with reference to the drawings.

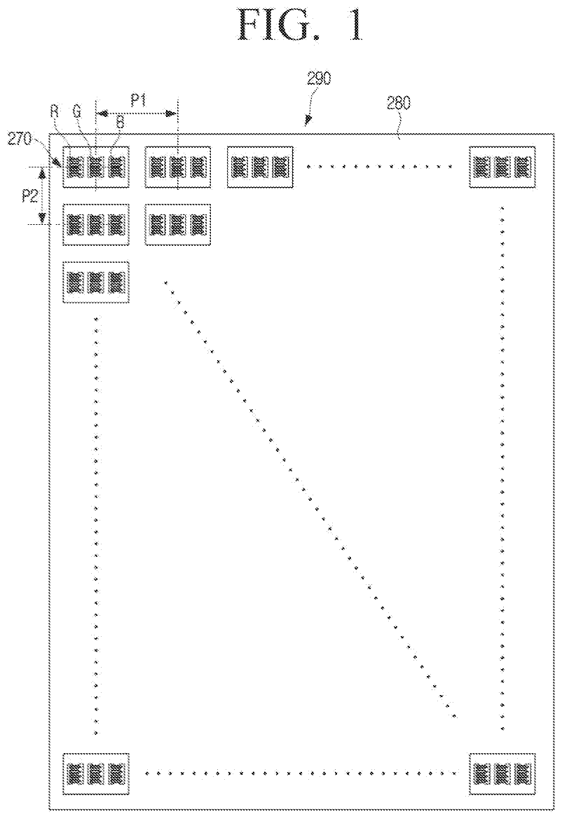

FIG. 1 is a diagram illustrating a display module according to an embodiment of the disclosure.

Referring to FIG. 1, the display module 290 according to an embodiment of the disclosure may include a plurality of unit pixels 270 arranged on the TFT substrate 280. The plurality of unit pixels 270 may include a plurality of sub-pixels. Here, one sub-pixel may include a plurality of nanowire LEDs.

A nanowire LED is a semiconductor chip consisting of an inorganic light emitting material, and it may emit a light by itself in case power is supplied. A nanowire LED may implement a real high dynamic range (HDR), and may provide improved luminance and representation of a black color, and a higher contrast ratio compared to an OLED. The size of a nanowire LED may be from scores of nm to scores of μm.

The plurality of unit pixels 270 may be arranged in a lattice form on the TFT substrate 280. For example, the plurality of unit pixels 270 may be arranged by a first pitch P1 in a row direction, and may be arranged by a second pitch P2 in a column direction. The first pitch P1 and the second pitch P2 may be set to be identical or different, in consideration of the size of the display module to be manufactured.

The TFT substrate 280 may include a glass substrate, a TFT layer including a TFT circuit on the front surface of the glass substrate, and a plurality of side surface wirings electronically connecting the TFT circuit of the TFT layer and circuits arranged on the rear surface of the glass substrate. The TFT substrate 280 may include an active area expressing an image, and a dummy area that cannot express an image on the front surface.

The pixel driving method of the display module 290 according to an embodiment of the disclosure may be an active matrix (AM) driving method or a passive matrix (PM) driving method. The display module 290 may form a pattern of wirings to which each nanowire LED is electronically connected according to the AM driving method or the PM driving method.

The dummy area may be included in the edge area of the glass substrate, and a plurality of first connection pads may be arranged at a specific interval from one another. Each of the plurality of first connection pads may be electronically connected to each sub-pixel through a wiring.

The number of the first connection pads formed in the dummy area may vary according to the number of pixels implemented on the glass substrate, and it may also vary according to the driving method of the TFT circuit arranged in the active area. For example, compared to the passive matrix (PM) driving method where the TFT circuit arranged in the active area drives a plurality of pixels in a horizontal line and a vertical line, the AM driving method where each pixel is independently driven may need more wirings and connection pads.

The display module 290 may include a transparent cover layer for protecting the front surface of the TFT substrate 280 on which the plurality of unit pixels 270 are mounted. In this case, on the front surface of the TFT substrate, a spacer for supporting the transparent cover layer may be arranged. The spacer may have a black tone color so that it may absorb lights emitted from each unit pixel 270 and external lights of the display module 290. Also, the display module 290 may include a touch screen panel stacked on the front surface of the transparent cover layer.

Hereinafter, nanowire LEDs and the structure and the manufacturing process of the display module to which the nanowire LEDs are applied will be described sequentially with reference to the drawings.

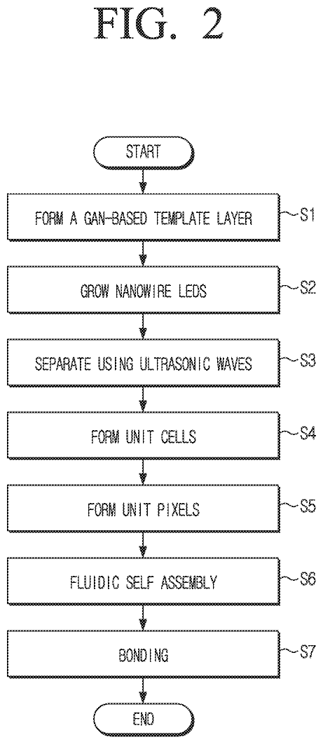

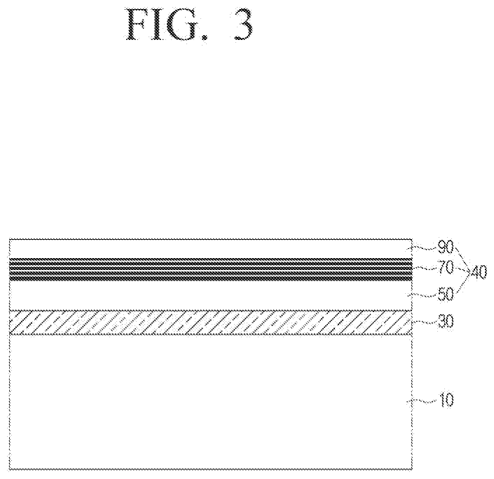

FIG. 2 is a flowchart illustrating a manufacturing process of a display module according to an embodiment of the disclosure. FIG. 3 is a diagram illustrating an example of forming a GaN-based template layer on a substrate according to an embodiment of the disclosure.

Referring to FIG. 2 and FIG. 3, after a Ge buffer layer 30 is formed on the silicon substrate 10, an n-GaN-based template layer 40 for growing nanowire LEDs in a three-dimensional shape is formed on the Ge buffer layer 30 in operation S1.

The Ge buffer layer 30 grown on the silicon substrate 10 may minimize a lattice mismatch between the silicon substrate 10 and the n-GaN-based template layer 40. On the Ge buffer layer 30, a Ge layer and a GaN layer may be formed in stack alternatingly in a repeated manner.

In the case of applying the Ge buffer 30 as above, the dislocation density between the silicon substrate 10 and the n-GaN-based template layer 40 may be reduced, and the mismatch rate may be maintained to be about 0.08% or lower. Accordingly, the threading dislocation density (TDD) of the n-GaN-based template layer 40 becomes—E7/cm², and thus a basis for growing nanowire LEDs that will proceed in a later process may be provided.

The n-GaN-based template layer 40 may include a first GaN layer 50 that is the most adjacent to the Ge buffer layer 30, a magnetic layer 70 stacked on the first GaN layer 50, and a second GaN layer 90 stacked on the magnetic layer 70.

The magnetic layer 70 constitutes a part of nanowire LEDs together with the second GaN layer 90. In such nanowire LEDs having a magnetic property, a plurality of nanowire LEDs included in the unit cells may be aligned in one direction by using a magnetic field in a later process.

On the magnetic layer 70, a plurality of n-GaN-based first thin film layers and a plurality of second thin film layers having a magnetic property may be formed in stack alternatingly in a repeated manner. In this case, the plurality of second film layers may be a diamagnetic material, e.g., Ge, or a material having a magnetic property, e.g., any one of Cr, Mn, Fe, Co, Ni, and Cu. Meanwhile, the magnetic layer 70 may be a thin film superlattice (e.g., a strained-layer superlattice (SLS)) layer that has a magnetic property, and where stress is accumulated.

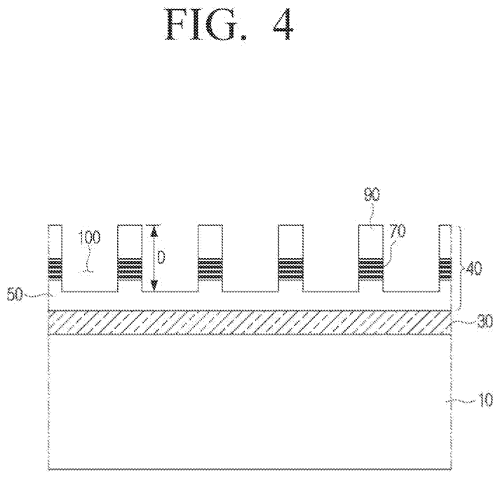

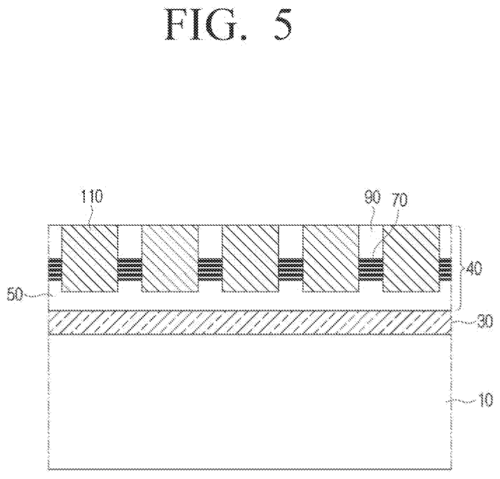

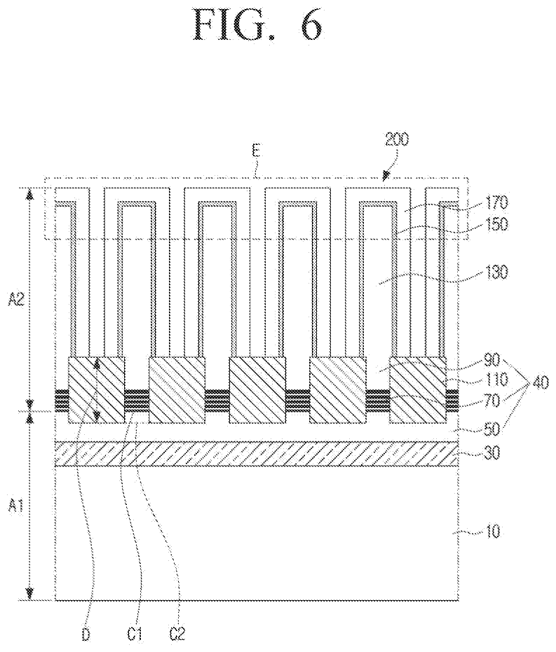

FIG. 4 is a diagram illustrating an example of forming a plurality of grooves by etching a part of a GaN-based template layer according to an embodiment of the disclosure. FIG. 5 is a diagram illustrating an example of inserting a filling material into a plurality of grooves formed on a GaN-based template layer according to an embodiment of the disclosure. FIG. 6 is a diagram illustrating an example of growing a plurality of nanowire LEDs in a three-dimensional shape on a GaN-based template layer according to an embodiment of the disclosure.

On the n-GaN-based template layer 40, the nanowire LEDs 200 are grown in operation S2. For growth of the nanowire LEDs 200, the following process may be performed.

Referring to FIG. 4, a filling part 100 is patterned on the n-GaN-based template layer 40 through an etching process or a photolithography process.

The filling part 100 may be formed in a specific depth D by a top-down method toward the Ge buffer layer 30 from the surface of the n-GaN-based template layer 40.

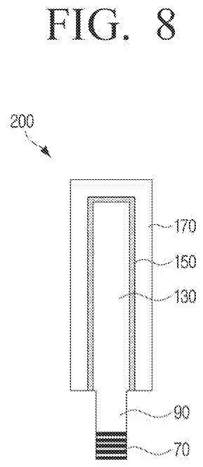

In this case, by adjusting the depth D of the filling part 100, the length of a part that is not covered by the p-type semiconductor layer 170 (refer to FIG. 8) of the nanowire LEDs 200 and is exposed to the outside (referred to as ‘the exposed part of the nanowire LEDs 200’ hereinafter) may be determined.

The exposed part of the nanowire LEDs 200 is a part of the n-GaN-based template layer 40 that is integrally formed on the n-type semiconductor layer 130 of the nanowire LEDs 200, and in a later process, it is electronically and physically connected to the cathode electrode through bonding.

Referring to FIG. 5, a filling material 110 is infiltrated into the filling part 100 for stably growing the nanowire LEDs 200 on the n-GaN-based template layer 40, and the surface of the n-GaN-based template layer 40 is made approximately flat.

The filling material 110 supports the exposed part of the nanowire LEDs 200. The nanowire LEDs 200 grown on the n-GaN-based template layer 40 are separated from the n-GaN-based template layer 40 by ultrasonic waves in a later process. In this case, the part separated by the ultrasonic waves is the exposed part of the nanowire LEDs 200.

The filing material 110 may include a synthetic resin having flexibility, e.g., polyimide (PI), so that ultrasonic waves may be stably transmitted to the exposed part of the nanowire LEDs 200.

The exposed part of the nanowire LEDs 200 may be easily cut and separated from the n-GaN-based template layer 40 by ultrasonic waves.

Referring to FIG. 6, the nanowire LEDs 200 are grown in a three-dimensional shape on the n-GaN-based template layer 40.

The n-type semiconductor layer 130 is grown by the bottom-up method. The n-type semiconductor layer 130 is a cladding layer, and may include n-GaN.

Then, an active layer 150 is formed on the surface of the n-type semiconductor layer 130. The active layer 150 may include a multi quantum wells (MQWs) structure in which well structures, where a very thin light emitting layer (an active layer) and a very thin insulation layer (or a barrier layer) are alternatingly stacked, are formed in multiple layers, for increasing the coupling efficiency of electrons and holes quantum-mechanically.

Then, the p-type semiconductor layer 170 is formed on the surface of the active layer 150. The p-type semiconductor layer 170 is a cladding layer, and may include p-GaN.

As described above, the plurality of nanowire LEDs 200 are grown on the n-GaN-based template layer 40, and then a hydrophilic surface treatment is performed on the surface of the p-type semiconductor layer 170 falling under the end part (refer to the part ‘E’ indicated in FIG. 6) of the plurality of nanowire LEDs 200.

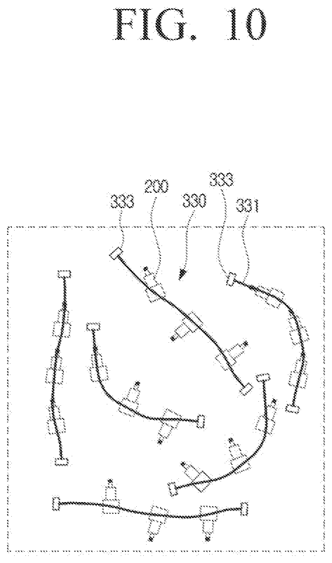

The hydrophilic surface treatment is a preceding measure for coupling the plurality of nanowire LEDs to a bridging point of a polymer compound (refer to the ring-shaped compound 335 in FIG. 10) in a later process.

As hydrophilic surface treatment methods for modifying the end part of the plurality of nanowire LEDs 200 to be hydrophilic, there are a chemical treatment method, an ultraviolet ray irradiation method, an oxygen plasma treatment method, etc.

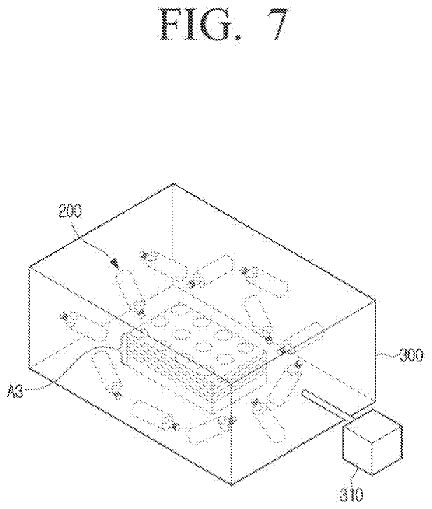

FIG. 7 is a diagram illustrating an example of separating a plurality of nanowire LEDs from a substrate by using ultrasonic waves according to an embodiment of the disclosure. FIG. 8 is a cross-sectional view illustrating nanowire LEDs separated from a substrate according to an embodiment of the disclosure.

The plurality of nanowire LEDs 200 grown on the n-GaN-based template layer 40 are separated from the n-GaN-based template layer 40 by using ultrasonic waves in operation S3.

Referring to FIG. 7, the silicon substrate 10 on which the plurality of nanowire LEDs 200 have grown is put into a predetermined tank 300 into which a solution has been loaded, and an ultrasonic wave generator 310 is operated. Ultrasonic waves generated from the ultrasonic wave generator are transmitted to the silicon substrate with the solution as the transmission medium.

By vibration due to the ultrasonic waves, the part connecting the n-GaN-based template layer 40 and the plurality of nanowire LEDs 200 is cut. Referring to FIG. 6, the cut part may be the boundary surface C1 of the first GaN layer 50 and the magnetic layer 70, or between a portion C2 of the first GaN layer 50 corresponding to the bottom surface of the filling part 110 and the boundary surface C1.

In this case, the depth D of the filling part 110 may be a standard for determining the length of the exposed part of the nanowire LEDs 200, as described above.

Referring to FIG. 8, the plurality of nanowire LEDs 200 separated from the n-GaN-based template layer 40 may include a pillar shape on the whole while including the exposed part of the nanowire LEDs 200.

There is no need to form the exposed part (the part adjacent to the magnetic layer 70) which is a portion of the n-type semiconductor layer of the plurality of nanowire LEDs 200 through etching, unlike in the related art technology. Accordingly, no damage is exerted to the nanowire LEDs 200, and thus degradation of the performance of the nanowire LEDs 200 that may occur in the separation process may be fundamentally prevented. Also, compared to a conventional etching process, a simple ultrasonic process proceeds, and thus the time spent for the process may be reduced, and the cost may be saved.

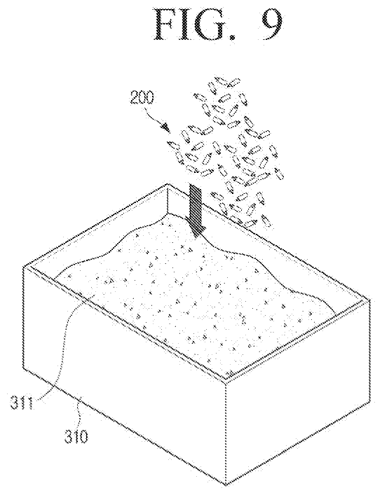

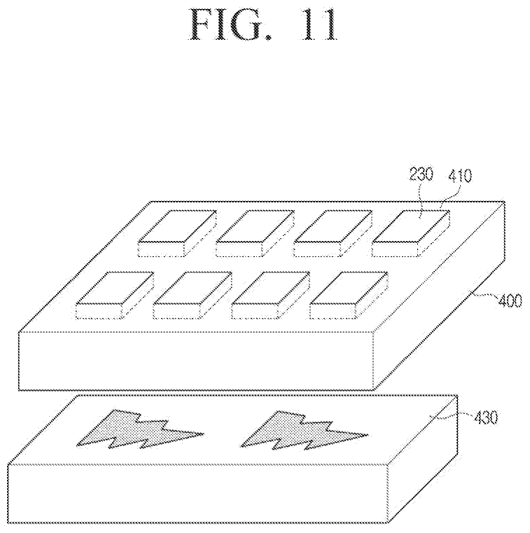

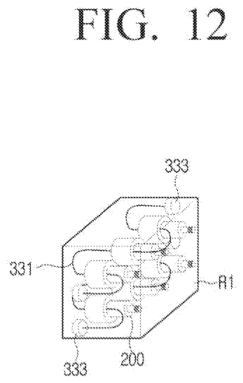

FIG. 9 is a diagram illustrating an example of introducing a plurality of nanowire LEDs into a tank including a polymer compound according to an embodiment of the disclosure. FIG. 10 is a diagram illustrating an example where a plurality of nanowire LEDs are respectively coupled to a plurality of ring-shaped compounds included in a polymer compound according to an embodiment of the disclosure. FIG. 11 is a diagram illustrating an example of infiltrating nanowire LEDs coupled with a polymer compound into a plurality of molding grooves formed on a mold, and forming a magnetic field around the mold according to an embodiment of the disclosure. FIG. 12 is a diagram illustrating an example wherein a plurality of nanowire LEDs arranged in a unit cell are aligned in a specific direction by a magnetic field according to an embodiment of the disclosure.

A unit cell 230 is formed through the following process by using the plurality of nanowire LEDs in operation S4. For manufacturing the unit cell 230, the following process may be performed.

Referring to FIG. 9, the plurality of nanowire LEDs 200 are introduced into a predetermined tank 310 into which a compound solution 311 including a polymer compound and a binder has been loaded.

Referring to FIG. 10, the polymer compound may be, for example, polyrotaxane which is a compound where dumbbell-shaped molecules and ring-shaped compounds (macrocycles) 335 are structurally fitted.

The dumbbell-shaped molecules include regular linear molecules 331 and blocking groups 333 coupled respectively to both ends of the linear molecules 331. The linear molecules 331 penetrate through the insides of the ring-shaped compounds 335. The ring-shaped compounds 335 may move along the linear molecules 331, and their detachment from the linear molecules 331 is prevented by the blocking groups 333.

In the plurality of nanowire LEDs 200 introduced into the compound solution 311, the end parts that respectively went through a hydrophilic treatment (the part ‘E’ indicated in FIG. 6) are coupled to the ring-shaped compounds 335. To one ring-shaped compound 335, one nanowire LED 200 is coupled.

The nanowire LEDs 200 coupled to the ring-shaped compounds 335 cannot be detached from the linear molecules 331. The nanowire LEDs 200 may change their postures freely in various directions. Accordingly, the plurality of nanowire LEDs 200 may be aligned in a specific direction by a magnetic field in a later process.

Referring to FIG. 11, the plurality of nanowire LEDs 200 are infiltrated into a plurality of molding grooves 410 formed on the mold 400 together with the solution 311.

In this case, as the plurality of nanowire LEDs 200 are in a state of being connected to the respective ring-shaped compounds 335, the density of the nanowire LEDs 200 infiltrated into each molding groove 410 may be homogenized.

In the state where the plurality of nanowire LEDs 200 have been infiltrated into the plurality of molding grooves 410, a magnetic field generation device 430 arranged adjacently to the mold 400 is operated, and a magnetic field is formed in a specific direction.

Referring to FIG. 12, the plurality of nanowire LEDs 200 infiltrated into each molding groove 410 include a magnetic layer 70, and thus all of the nanowire LEDs 200 are aligned in the same direction as they are influenced by the magnetic field generated from the magnetic field generation device 430.

Then, the plurality of nanowire LEDs 200 infiltrated into each molding groove 410 are cooled to approximately 30° C. or lower together with the solution 311, and a unit cell 230 in a gel state is formed. The plurality of nanowire LEDs 200 included in the unit cell 230 formed in a gel state may be protected from an external shock that is applied during the process.

One unit cell 230 may correspond to one sub-pixel. Accordingly, depending on the size of the sub-pixel required through the above process, the size of the unit cell 230 may be changed. In this case, the number of the plurality of nanowire LEDs 200 included in the unit cell 230 is also changed. As described above, the disclosure may provide a unit cell that may respond flexibly to the required size of a sub-pixel.

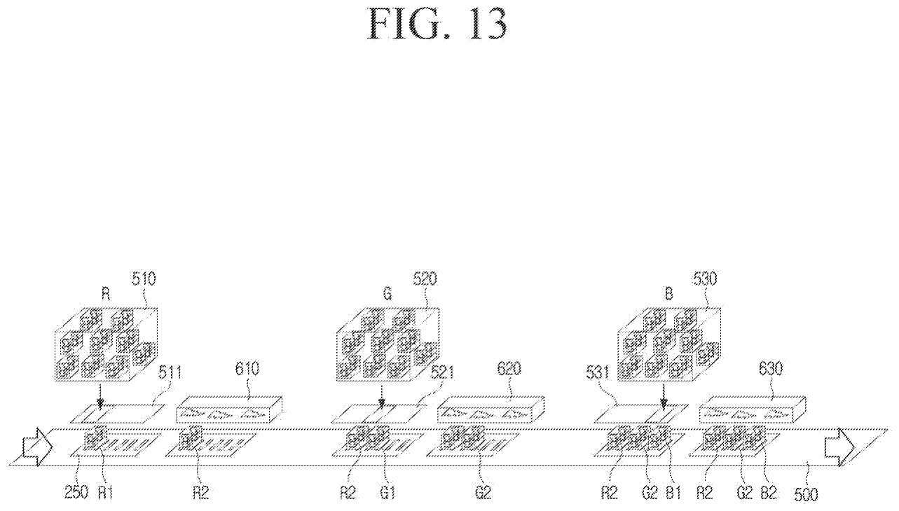

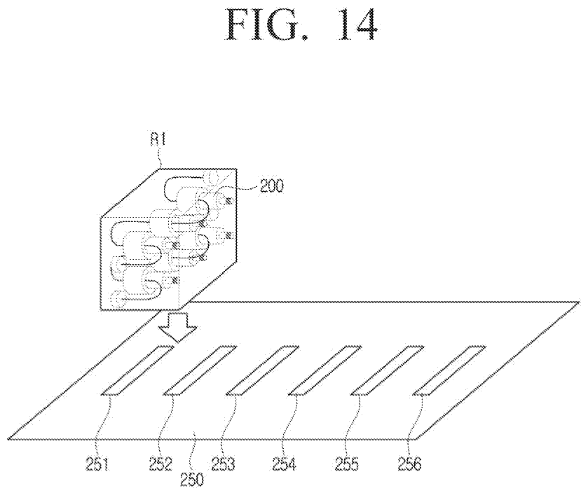

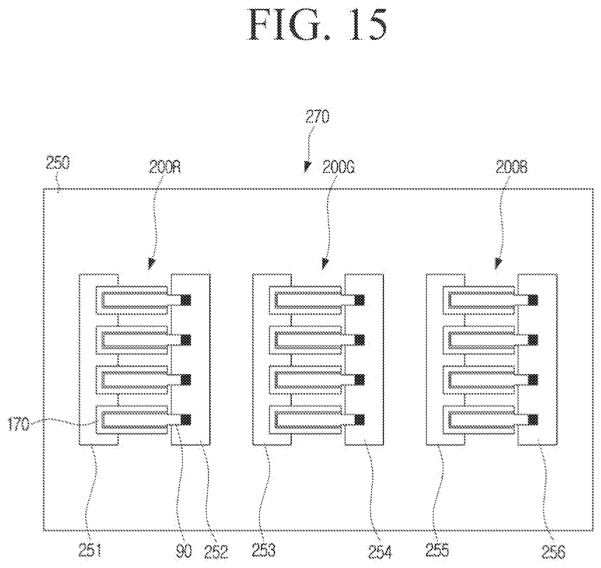

FIG. 13 is a diagram illustrating an example of transferring red/green/blue nanowire LEDs constituting one pixel to a unit substrate according to an embodiment of the disclosure. FIG. 14 is a diagram illustrating a state where nanowire LEDs in a unit cell form are transferred to the unit substrate illustrated in FIG. 13 according to an embodiment of the disclosure. FIG. 15 is a diagram illustrating a plurality of nanowire LEDs connected to an anode electrode and a cathode electrode on a unit substrate according to an embodiment of the disclosure

A plurality of unit cells 230 are transferred to a unit substrate 250, and a unit pixel 270 is formed in operation S5. The following process may be performed for manufacturing the unit pixel 270.

The unit substrate 250 falls under some features of the unit pixel 270 constituting one pixel while including a plurality of sub-pixels (nanowire LEDs).

Referring to FIG. 13, the unit substrate 250 is loaded on a conveyor 500 moving in one direction. On the upper side of the conveyor 500, a first hopper 510 containing unit cells including a plurality of nanowire LEDs emitting a red color (referred to as ‘red unit cells’ hereinafter), a second hopper 520 containing unit cells including a plurality of nanowire LEDs emitting a green color (referred to as ‘green unit cells’ hereinafter), and a third hopper 530 containing unit cells including a plurality of nanowire LEDs emitting a blue color (referred to as ‘blue unit cells’ hereinafter) may be arranged at a specific interval along the longitudinal direction of the conveyor 500.

Also, on the lower side of the first to third hoppers 510, 520, 530, first to third mask devices 511, 521, 531 may be respectively arranged.

Also, on the upper side of the conveyor 500, first to third magnetic field generation devices 610, 620, 630 may be arranged. The first magnetic field generation device 610 may be arranged between the first and second hoppers 510, 520, the second magnetic field generation device 620 may be arranged between the second and third hoppers 520, 530, and the third magnetic field generation device 630 may be arranged on one side of the third hopper 530.

The unit substrate 250 that is loaded on the conveyor 500 and moves in one direction passes by the lower side of the mask device 511 including a shutter that is arranged on the lower side of the first hopper 510. Here, when the unit substrate 250 is detected by a sensor, the red unit cells R1 discharged from the first hopper 510 may be received in the locations of the red sub-pixels of the unit substrate 250 through the opening of the first mask device 511, as in FIG. 13.

Then, the red unit cells R1, which are received on the unit substrate 250 and move, pass by the lower side of the first magnetic field generation device 610, and align their postures such that the p-type semiconductor layer 170 of the plurality of nanowire LEDs 200 is toward the anode electrode 251 side of the unit substrate 250, and a part 90 of the n-type semiconductor layer 130 is toward the cathode electrode 252, by the magnetic field generated from the first magnetic field generation device 610.

Then, on the unit substrate 250, the green unit cells G1 are received in the locations of the green sub-pixels of the unit substrate 250, and then their postures are aligned by the magnetic field generated from the second magnetic field generation device 620.

Then, on the unit substrate 250, the blue unit cells B1 are received in the locations of the blue sub-pixels of the unit substrate 250, and then their postures are aligned by the magnetic field generated from the third magnetic field generation device 630.

In this case, all of the numbers of the unit cells discharged at one time from the first to third hoppers 510, 520, 530 are identical. For example, if one red unit cell is discharged from the first hopper 510, one green unit cell and one blue unit cell are discharged respectively from the second and third hoppers 520, 530 sequentially.

On the unit substrate 250, the postures of the red, green, and blue unit cells R1, G1, B1 are aligned to correspond to each electrode. In this state, the unit substrate 250 passes by a section for removing the polymer compound by the conveyor 500.

In the section for removing the polymer compound, a polymer compound removing solution is sprayed to the moving unit substrate 250. Accordingly, the polymer compound constituting the red, green, and blue unit cells R1, G1, B1 is removed, and on the unit substrate 250, red, green, and blue nanowire LEDs 200R, 200G, 200B remain, as in FIG. 15.

In this state, both ends of the red, green, and blue nanowire LEDs 200R, 200G, 200B are pre-bonded to the respective corresponding cathode electrodes 251, 253, 255 and anode electrodes 252, 254, 256.

In the pre-bonding, contact metal (e.g., Ni/Au, In, ITO, etc.) is bonded to the p-type semiconductor layer of the nanowire LEDs.

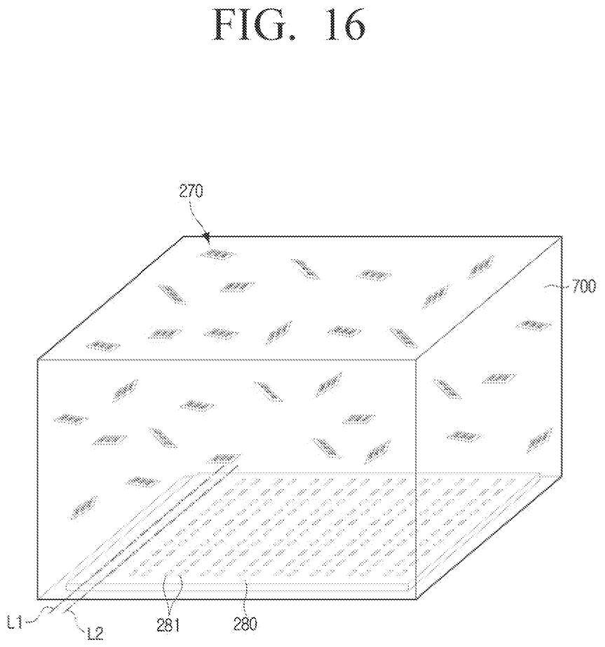

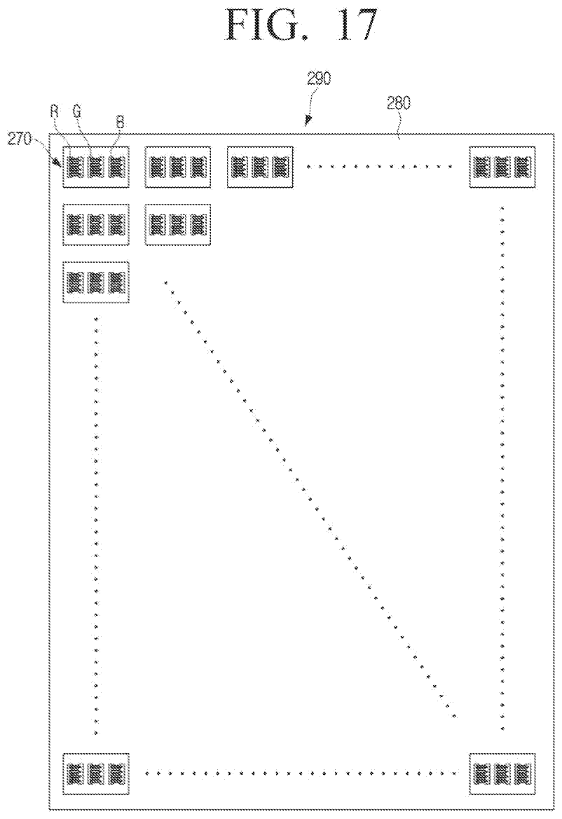

FIG. 16 is a diagram illustrating an example of arranging a plurality of unit pixels on a TFT substrate through fluidic self-assembly (FSA) according to an embodiment of the disclosure. FIG. 17 is a diagram illustrating a state where a plurality of unit pixels arranged on a TFT substrate are bonded to electrodes of the TFT substrate according to an embodiment of the disclosure.

The plurality of unit substrates 250 on which the red, green, and blue nanowire LEDs 200R, 200G, 200B are arranged are aligned on the TFT substrate 280 through an FSA process in operation S6, and the plurality of aligned unit substrates 250 are bonded to the electrodes 281 of the TFT substrate 280 in operation S7, and the display module 290 may thereby be manufactured.

Before the FSA process, a hydrophilic surface treatment is performed respectively on each unit substrate 250 and the TFT substrate 280.

For example, a hydrophilic surface treatment is performed on the anode electrode formed on the rear surface (the opposite surface of the surface to which sub-pixels are bonded) of each unit substrate 250, and a hydrophilic surface treatment is performed on the TFT substrate 280 along the column L1 where a plurality of anode electrodes are located. Alternatively, a hydrophilic surface treatment is performed on the cathode electrode formed on the rear surface (the opposite surface of the surface to which sub-pixels are bonded) of each unit substrate 250, and a hydrophilic surface treatment is performed on the TFT substrate 280 along the column L2 where a plurality of cathode electrodes are located.

Referring to FIG. 16, the TFT substrate 280 that went through a hydrophilic treatment is introduced into a predetermined tank 700 into which a solution for FSA has been loaded, and then the plurality of unit substrates 250 that went through a hydrophilic treatment are introduced into the tank 700.

As the solution inside the tank 700 is circulated, the plurality of unit substrates 250 floating in the solution flow inside the tank 700, and are then attached to the part that went through a hydrophilic surface treatment of the TFT substrate 280. Through such a FSA process, the plurality of unit substrates 250 are aligned in each location on the TFT substrate 280.

As in FIG. 17, when the plurality of unit substrates 250 are aligned in each location on the TFT substrate 280, the TFT substrate 280 is withdrawn from the tank, and then heat is applied to the TFT substrate 280, and through this, a eutectic bonding process proceeds such that the electrodes of the plurality of unit substrates 250 are respectively connected to the electrodes 281 of the TFT substrate 280 electronically and physically.

In the eutectic bonding process, the contact metal used in bonding the p-type semiconductor layer of the nanowire LEDs may be Ni/Au, and the contact metal used in bonding the n-type semiconductor layer may be Ti/Au.

Before the FSA process, a hydrophilic surface treatment was performed respectively to each unit substrate 250 and the TFT substrate 280. However, the disclosure is not limited thereto, and a hydrophobic surface treatment may be performed instead of a hydrophilic surface treatment.

The display module 290 formed as above may be manufactured in a small size of about 7 inches-10 inches. A plurality of display modules 290 manufactured in small sizes may be connected, and a large format display device having a big screen size (e.g., 100 inches or bigger) may be manufactured.

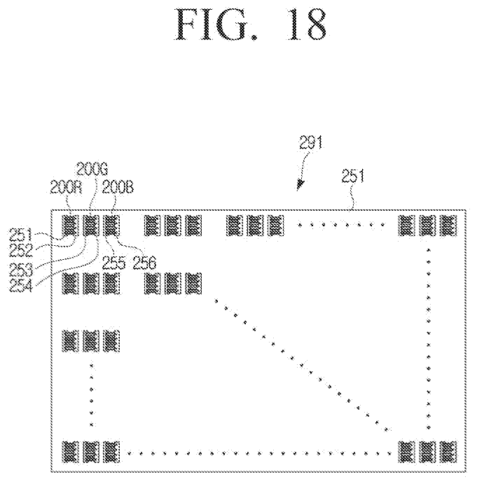

FIG. 18 is a diagram illustrating a display module according to an embodiment of the disclosure.

Referring to FIG. 18, in a display module 291 according to another embodiment of the disclosure, a unit substrate is not formed, but red, green, and blue unit cells may be received in each location of a TFT substrate 281 directly through the process illustrated in FIG. 13, and then a magnetic field may be applied, and the postures of the unit cells may be aligned in a specific direction on the TFT substrate 281.

Then, a polymer compound constituting a part of the unit cells may be removed, and then red, green, and blue nanowire LEDs 200R, 200G, 200B may be electronically and physically connected to the TFT substrate 281 through a eutectic bonding process.

While the various embodiments of the disclosure have been described separately from one another, the embodiments do not have to be implemented independently, but the configuration and operation of each embodiment may be implemented in combination with at least one other embodiment.

Also, while embodiments of the disclosure have been shown and described, the disclosure is not limited to the aforementioned specific embodiments, and it is apparent that various modifications may be made by those having ordinary skill in the technical field to which the disclosure belongs, without departing from the gist of the disclosure as claimed by the appended claims. Further, it is intended that such modifications are not to be interpreted independently from the technical idea or prospect of the disclosure.

What is claimed is:

1. A nanowire light emitting diode comprising:
an n-type GaN-based semiconductor layer having a pillar shape;
an active layer provided on a first side of the n-type GaN-based semiconductor layer;
a p-type GaN-based semiconductor layer provided on the active layer; and
a magnetic layer provided on a second side of the n-type GaN-based semiconductor layer.

2. The nanowire light emitting diode of claim 1, wherein the magnetic layer is provided on an end part of the second side of the n-type GaN-based semiconductor layer.

3. The nanowire light emitting diode of claim 1, wherein the magnetic layer comprises a diamagnetic material.

4. The nanowire light emitting diode of claim 3, wherein the diamagnetic material comprises Ge.

5. The nanowire light emitting diode of claim 1, wherein the magnetic layer comprises a material having a magnetic property.

6. The nanowire light emitting diode of claim 5, wherein the material having the magnetic property comprises Cr, Mn, Fe, Co, Ni, or Cu.

7. The nanowire light emitting diode of claim 1, wherein the magnetic layer comprises:
at least one first thin film layer comprising a diamagnetic material or a material having a magnetic property; and
at least one second thin film layer comprising an n-type semiconductor, and
wherein the at least one first thin film layer and the at least one second thin film layer are alternatingly stacked.

8. A display module comprising:
a thin film transistor (TFT) substrate comprising a plurality of anode electrodes and a plurality of cathode electrodes provided on a first surface of the TFT substrate; and
a plurality of nanowire light emitting diodes (LEDs) comprising first end parts respectively connected to each anode electrode and second end parts respectively connected to each cathode electrode,
wherein each of the plurality of nanowire LEDs has a magnetic property and polarity.

9. The display module of claim 8, wherein the plurality of nanowire LEDs comprises:
an n-type GaN-based semiconductor layer having a pillar shape;
an active layer provided on a first side of the n-type GaN-based semiconductor layer;
a p-type GaN-based semiconductor layer provided on the active layer; and
a magnetic layer provided on a second side of the n-type GaN-based semiconductor layer.

10. The display module of claim 8, wherein the plurality of nanowire LEDs are provided to the TFT substrate in a form of a unit pixel comprising red, green, and blue sub-pixels, and
wherein the unit pixel comprises a unit substrate on which the red, green, and blue sub-pixels are provided.

11. A method for manufacturing a display module, the method comprising:
forming a template layer comprising a magnetic layer on a silicon substrate;
growing a plurality of nanowire light emitting diodes (LEDs) on the template layer;
separating the plurality of nanowire LEDs from the template layer by ultrasonic waves;
forming a plurality of unit cells in a state in which the plurality of nanowire LEDs are aligned to have a specific directivity;
forming a plurality of unit pixels by transferring the plurality of unit cells onto a unit substrate;
arranging the plurality of unit pixels on a thin film transistor (TFT) substrate through a fluidic self-assembly; and
bonding the plurality of unit pixels to be connected to an electrode of the TFT substrate.

12. The method of claim 11, wherein the forming the template layer comprises:
forming a first n-type GaN-based semiconductor layer on the silicon substrate;
forming the magnetic layer by alternatingly stacking at least one first thin film layer comprising an n-type semiconductor and at least one second thin film layer comprising a diamagnetic material or a material having a magnetic property on the first n-type GaN-based semiconductor layer; and
forming a second n-type GaN-based semiconductor layer on the magnetic layer.

13. The method of claim 12, wherein the diamagnetic material comprises Ge, and
wherein the material having the magnetic property comprises Cr, Mn, Fe, Co, Ni, or Cu.

14. The method of claim 11, further comprising, prior to growing the plurality of nanowire LEDs:
patterning a filling part on the template layer, and
infiltrating a filling material having flexibility into the filling part.

15. The method of claim 14, further comprising:
setting a length of an exposed part of the plurality of nanowire LEDs based on a depth of the filling part.
